(19) United States
(12) Patent Application Publication
(10) Pub. No.: US 2013/0022745 A1
(43) Pub. Date: Jan. 24, 2013

(54) SILANE BLEND FOR THIN FILM VAPOR DEPOSITION

(71) Applicants: Christian Dussarrat, Wilmington, DE (US); Vincent M. Omarjee, Grenoble (FR); Venkateswara R. Pallem, Hockessin, DE (US)

(72) Inventors: Christian Dussarrat, Wilmington, DE (US); Vincent M. Omarjee, Grenoble (FR); Venkateswara R. Pallem, Hockessin, DE (US)

(73) Assignee: AMERICAN AIR LIQUIDE, INC., Fremont, CA (US)

(21) Appl. No.: 13/390,495

(22) PCT Filed: Aug. 13, 2010
(86) PCT No.: PCT/US2010/045484

§ 371 Date: May 11, 2012

Related U.S. Application Data
(60) Provisional application No. 61/233,916, filed on Aug. 14, 2009.

(51) Int. Cl. C23C 16/40; C23C 16/06; C23C 16/24; C23C 16/34

(52) U.S. Cl. 427/255.28; 427/248.1

(57) ABSTRACT

Disclosed are non-pyrophoric mixtures of silicon compounds and solvents. Also disclosed are methods of stabilizing the pyrophoric silicon compounds (precursors). The non-pyrophoric mixtures may be used to deposit silicon-containing layers using vapor deposition methods such as chemical vapor deposition or atomic layer deposition.

### TECHNICAL FIELD

Disclosed are vapor deposition methods of forming a silicon-containing layer on a substrate using a blend of a silane and a solvent.

### BACKGROUND

Many precursors exhibit pyrophoric characteristics, i.e. they spontaneously catch fire upon exposure to ambient air (e.g., trimethylaluminum “TMA”; triethylaluminum “TEA”, dimethylaluminum hydride “DMAH”, trimethylgallium “TMGa”, trimethylboron “TMB”, diethylzinc “DEZ”, mono-silane, etc). For example, Kondo et al. demonstrated the instability of silane (SiH₄) in the presence of oxygen, even with a very low concentration of oxygen in a diluted mixture of Silane/N₂. Kondo et al., Combustion and Flame 101:170-174 (1995).

Nonetheless, these pyrophoric products have found usage in various industries, ranging from catalysis to thin film deposition (semiconductor applications, optoelectronics applications, photovoltaic applications). Use of these products is subject to very strict limitations in terms of shipment, storage conditions, delivery, fire-fighting measures, etc.

Vapor deposition of silane precursors has been disclosed in the art. See, e.g., U.S. Pat. Nos. 4,683,145; 5,593,497; and 5,910,342. However, these vapor deposition methods have not been commercially embraced. These methods require delivery of the silicon precursor by specialized delivery systems, which are equipped with specific features such as an oil trap for the purge vent line, N₂ flush capability in case of fire detection, and a line flush back mechanism to empty the distribution line between refills of the point of use capacity. These special safety measures add significant cost and complications for safe usage of the precursor.

To overcome these issues, liquid deposition of silane precursors has been promoted. See, e.g., U.S. Pat. Nos. 6,517,911; 7,173,180; and 7,223,802. These patents disclose dissolving the silane precursor and other ingredients in a solvent and coating the resulting solution on a substrate by spray coating, roll coating, curtain coating, spin coating, screen printing, offset printing, and ink-jet printing.

However, liquid deposition methods are not problem-free. For example, liquid deposition methods may have difficulty in providing continuous thin films due at least to voiding (i.e., formation of bubbles in the liquid). Vapor deposition methods are more reliable in providing conformal and continuous thin films.

Therefore, a need remains for vapor deposition methods of pyrophoric silane precursors.

### SUMMARY

Disclosed are silane/solvent blends and methods of using them to form a silicon-containing layer on a substrate disposed in a reactor. A vapor of the silane/solvent blend is introduced into the reactor. The silane may be selected from the group consisting of (a) a polysilane and (b) a monoaminosilane having a formula H₃Si[amine] wherein [amine] is a cyclic amine or —(NR₁R₂) with R₁ and R₂ each independently selected from hydrogen and an aliphatic group having 1 to 6 carbon atoms. A vapor deposition process is used to form a silicon-containing layer on at least one surface of the substrate. The disclosed blends and methods may include one or more of the following aspects:

the polysilane being cyclopentasilane or cyclohexasilane;

the cyclic amine of the monoaminosilane being piperidine or pyrrolidine;

the silane being selected from the group consisting of diisopropylaminosilane, ditertbutylaminosilane, piperidinosilane, pyrrolidinosilane, and mixtures thereof;

the solvent being selected from the group consisting of dichloromethane, acetone, pentane, hexane, heptane, octane, decane, dodecane, ethyl ether, and mixtures thereof;

the solvent being selected from the group consisting of toluene, mesitylene, xylene, and mixtures thereof;

the silane to solvent ratio being lower than 1 to 2, more preferably lower than 1 to 8;

introducing at least one second precursor into the reactor;

the second precursor being a metal-containing compound comprising a metal selected from the group consisting of Ti, Ta, Bi, Hf, Zr, Pb, Nb, Mg, Al, Sr, Y, Ba, Ca, Ni, Co, lanthanides, and combinations thereof;

introducing at least one co-reactant into the reactor;

the co-reactant being an oxidizing gas selected from the group consisting of N₂, NH₃, O₂, O₃, H₂O, H₂O₂, carboxylic acid, and combinations thereof;

the vapor deposition process being a chemical vapor deposition process; and

the vapor deposition process being an atomic layer deposition process.

### NOTATION AND NOMENCLATURE

Certain terms are used throughout the following description and claims to refer to various components and constituents.

The standard abbreviations of the elements from the periodic table of elements are used herein. It should be understood that elements may be referred to by these abbreviations (e.g., Si refers to silicon, Zr refers to zirconium, Pd refers to palladium, Co refers to cobalt, etc).

As used herein, the term “silane” or “silanes” refer to polysilanes or monoaminosilanes, each of which is further defined below in the Detailed Description of Preferred Embodiments. As used herein, the term “aliphatic group” refers to a group of organic compounds which are carbon atoms are linked in open chains, such as alkanes, alkenes and alkynes; and the term “alkyl group” refers to saturated functional groups containing exclusively carbon and hydrogen atoms, Further, the term “alkyl group” may refer to linear, branched, or cyclic alkyl groups. Examples of linear alkyl groups include without limitation, methyl groups, ethyl groups, propyl groups, butyl groups, etc. Examples of branched alkyls groups include without limitation, isopropyl groups, t-butyl groups, etc. Examples of cyclic alkyl groups include without limitation, cyclopropyl groups, cyclopentyl groups, cyclohexyl groups, etc.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

### DETAILED DESCRIPTION OF PREFERRED EMBODIMENTS

Disclosed herein are non-limiting embodiments of methods, apparatus, and compounds which may be used in the manufacture of semiconductor, photovoltaic, LCD-TFT, or flat panel type devices. More specifically, disclosed are vapor deposition methods of forming a silicon-containing layer on a substrate using a blend of a silane and a solvent.

The disclosed blends contain silane compounds in solvent mixtures. The disclosed blends are not pyrophoric and are expected to allow a high deposition rate while achieving improved film properties. The solvent and silane precursor blend itself is designed to have suitable properties to be used in the semiconductor industry by vapor deposition processes. The blend is optimized to assure high vapor pressure with good thermal properties (good thermal stability) while achieving good reactivity.

As used herein, the term “silane” or “silanes” refer to polysilanes or monoaminosilanes. The silane is selected from the group consisting of (a) a polysilane and (b) a monoaminosilane having a formula H₃Si[amine] wherein [amine] is a cyclic amine or —(NR₁R₂) with R₁ and R₂ each independently selected from hydrogen and an aliphatic group having 1 to 6 carbon atoms. The polysilane may be cyclopentasilane or cyclohexasilane, preferably cyclohexasilane. The cyclic amine of the monoaminosilane may be piperidine or pyrrolidine. Exemplary silanes include cyclopentasilane, cyclohexasilane, diisopropylaminosilane, ditertbutylaminosilane, piperidinosilane, and pyrrolidinosilane, or mixtures thereof.

The solvent may be an organic solvent, such as dichloromethane, acetone, pentane, hexane, heptane, octane, decane, dodecane, and ethyl ether, and mixtures thereof. Alternatively, the solvent may be an aromatic hydrocarbon, such as toluene, mesitylene, xylene, and mixtures thereof.

Applicants have discovered that the volatility of the solvent needs to be lower or approximately equal to that of the silane. This prevents formation of a pyrophoric liquid upon evaporation of the solvent, for example, after a spill. Additionally, choosing a solvent with suitable volatility allows a vaporizer to deliver the blend with no concentration of either the silane or solvent occurring in the vaporized phase.

Finally, the solvent having a volatility close to that of the silane precursors allows for maintenance of the composition ratio between the silane precursor and the solvent in both the gas and liquid phases. Preferably, the silane precursor to solvent ratio is lower than 1 to 2, more preferably lower than 1 to 8.

Therefore, optimizing the blend to include silane and solvent components having vapor pressures of the same order of magnitude provides a blend having good thermal stability while achieving good reactivity.

Additionally, the disclosed blends improve the stability of the silane because the disclosed blend protects the silane from exposure to conditions that may cause its degradation, such as air and/or water.

Also disclosed are methods of forming a silicon-containing layer on a substrate (e.g., a semiconductor substrate or substrate assembly) using a vapor deposition process. The method may be useful in the manufacture of semiconductor structures. The method includes: providing a substrate, providing a vapor of the disclosed blend, and contacting the vapor with the substrate (and typically directing the vapor to the substrate) to form a silicon-containing layer on at least one surface of the substrate.

The disclosed blends may be deposited to form a thin film using any vapor deposition methods known to those of skill in the art. Examples of suitable vapor deposition methods include without limitation, conventional chemical vapor deposition (CVD), low pressure CVD (LPCVD), plasma enhanced chemical CVD (PECVD), atomic layer deposition (ALD), pulsed CVD (P-CVD), plasma enhanced atomic layer deposition (PE-ALD), or combinations thereof.

The disclosed blend is introduced into a reactor in vapor form. The vapor form may be produced by vaporizing the disclosed blend solution through a conventional vaporization step such as direct vaporization, distillation, or by bubbling. The disclosed blend may be fed in liquid state to a vaporizer where it is vaporized before it is introduced into the reactor. Alternatively, the disclosed blend may be vaporized by passing a carrier gas into a container containing the disclosed blend or by bubbling the carrier gas into the disclosed blend. The carrier gas may include, but is not limited to, Ar, He, N₂,and mixtures thereof. Bubbling with a carrier gas may also remove any dissolved oxygen present in the disclosed blend. The carrier gas and the disclosed blend are then introduced into the reactor as a vapor.

If necessary, the container of the disclosed blend may be heated to a temperature that permits the disclosed blend to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of the disclosed blend that is vaporized.

The reactor may be any enclosure or chamber within a device in which vapor deposition methods take place such as, and without limitation, a parallel-plate type reactor, a cold-wall type reactor, a hot-wall type reactor, a single-wafer reactor, a multi-wafer reactor, or other types of deposition systems under conditions suitable to cause the precursors to react and form the layers.

The reactor contains one or more substrates onto which the thin films will be deposited. The one or more substrates may be any suitable substrate used in semiconductor, photovoltaic, flat panel or LCD-TFT device manufacturing. Examples of suitable substrates include without limitation silicon substrates, silica substrates, silicon nitride substrates, silicon oxy nitride substrates, tungsten substrates, titanium nitride, tantalum nitride, or combinations thereof. Additionally, substrates comprising tungsten or noble metals (e.g. platinum, palladium, rhodium or gold) may be used. The substrate may also have one or more layers of differing materials already deposited upon it from a previous manufacturing step.

The temperature and the pressure within the reactor are held at conditions suitable for vapor depositions. For instance, the pressure in the reactor may be held between about 0.5 mTorr and about 20 Torr, preferably between about 0.2 Torr and 10 Torr, and more preferably between about 1 Torr and 10 Torr, as required per the deposition parameters. Likewise, the temperature in the reactor may be held between about 50° C. and about 600° C., preferably between about 50° C. and about 250° C., and more preferably between about 50° C. and about 100° C.

In addition to the disclosed blend, a co-reactant may be introduced into the reactor. The co-reactant may be an oxidizing gas, such as oxygen, ozone, water, hydrogen peroxide, carboxylic acids, nitric oxide, nitrogen dioxide, as well as mixtures of any two or more of these. Alternatively, the co-reactant may be a reducing gas, such as hydrogen, ammonia, a silane (e.g. SiH₄, Si₂H₆, Si₃H₈), an alkyl silane containing a Si—H bond (e.g. SiH₂Me₂, SiH₂Et₂), N(SiH₃)₃, as well as mixtures of any two or more of these. Preferably, the co-reactant is H₂ or NH₃.

The co-reactant may be treated by a plasma, in order to decompose the co-reactant into its radical form. N₂ may also be utilized as a reducing gas when treated with plasma. For instance, the plasma may be generated with a power ranging from about 50 W to about 500 W, preferably from about 100 W to about 200 W. The plasma may be generated or present within the reactor itself. Alternatively, the plasma may generally be at a location removed from the reaction chamber, for instance, in a remotely located plasma system. In this alternative, the co-reactant is treated with the plasma prior to introduction into the reactor. One of skill in the art will recognize methods and apparatus suitable for such plasma treatment.

The vapor deposition conditions within the chamber allow the disclosed blend and the optional co-reactant to form a silicon-containing film on at least one surface of the substrate. In some embodiments, Applicants believe that plasma-treating the optional co-reactant may provide the optional co-reactant with the energy needed to react with the disclosed blend.

Depending on what type of film is desired to be deposited, a second precursor may be introduced into the reactor. The second precursor may be another metal source, such as manganese, ruthenium, titanium, tantalum, bismuth, zirconium, hafnium, lead, niobium, magnesium, aluminum, strontium, yttrium, barium, calcium, nickel, cobalt, lanthanides, or mixtures of these. Where a second metal-containing precursor is utilized, the resultant film deposited on the substrate may contain at least two different metal types.

The disclosed blend and any optional co-reactants or precursors may be introduced into the reactor simultaneously (CVD), sequentially (ALD, P-CVD), or in other combinations. The disclosed blend and any optional co-reactants or precursors may be mixed together to form a co-reactant/precursor/blend mixture, and then introduced to the reactor in mixture form. Alternatively, the disclosed blend and/or co-reactant and/or precursor may be sequentially introduced into the reaction chamber and purged with an inert gas between each introduction. For example, the disclosed blend may be introduced in one pulse and two additional metal sources may be introduced together in a separate pulse [modified PE-ALD]. Alternatively, the reactor may already contain the co-reactant species prior to introduction of the disclosed blend, the introduction of which may optionally be followed by a second introduction of the co-reactant species. In another alternative, the disclosed blend may be introduced to the reactor continuously while other metal sources are introduced by pulse (pulse PECVD). In each example, a pulse may be followed by a purge or evacuation step to remove excess amounts of the component introduced. In each example, the pulse may last for a time period ranging from about 0.01 seconds to about 10 seconds, alternatively from about 0.3 seconds to about 5 seconds, alternatively from about 0.5 seconds to about 2 seconds.

Depending on the particular process parameters, deposition may take place for a varying length of time. Generally, deposition may be allowed to continue as long as desired or necessary to produce a film with the necessary properties. Typical film thicknesses may vary from several hundred angstroms to several hundreds of microns, depending on the specific deposition process. The deposition process may also be performed as many times as necessary to obtain the desired film.

In one non-limiting exemplary PE-ALD type process, the vapor phase of the disclosed blend is introduced into the reactor, where it is contacted with a suitable substrate. Excess disclosed blend may then be removed from the reactor by purging and/or evacuating the reactor, A reducing gas (for example, H₂) is introduced into the reactor under plasma power where it reacts with the absorbed disclosed blend in a self-limiting manner. Any excess reducing gas is removed from the reactor by purging o and/or evacuating the reactor. If the desired film is a silicon film, this two-step process may provide the desired film thickness or may be repeated until a film having the necessary thickness has been obtained.

Alternatively, if the desired film is a bimetal film, the two-step process above may be followed by introduction of the vapor of a metal-containing precursor into the reactor. The metal-containing precursor will be selected based on the nature of the bimetal film being deposited. After introduction into the reactor, the metal-containing precursor is contacted with the substrate. Any excess metal-containing precursor is removed from the reactor by purging and/or evacuating the reactor. Once again, a reducing gas may be introduced into the reactor to react with the metal-containing precursor. Excess reducing gas is removed from the reactor by purging and/or evacuating the reactor. If a desired film thickness has been achieved, the process may be terminated. However, if a thicker film is desired, the entire four-step process may be repeated. By alternating the provision of the disclosed blend, metal-containing precursor, and co-reactant, a film of desired composition and thickness can be deposited.

The silicon-containing films or silicon-containing layers resulting from the processes discussed above may include a pure silicon, metal silicate (MₖSiₗ), silicon oxide (SiₙOₘ), or silicon oxynitride (SiₓN_{y}O_{z}) film wherein k, l, m, n, x, y, and z are integers which inclusively range from 1 to 6. Preferably, the silicon-containing films are selected from a silicon film and SiO film, One of ordinary skill in the art will recognize that by judicial selection of the appropriate disclosed blend, optional metal-containing precursors, and optional co-reactant species, the desired film composition may be obtained.

### EXAMPLES

The following non-limiting examples are provided to further illustrate embodiments of the invention. However, the examples are not intended to be all inclusive and are not intended to limit the scope of the inventions described herein.

### Example 1

### Cyclohexasilane (CHS)-Mesitylene Solution (1:20)

A CHS mesitylene solution was prepared by dissolving 1 mL of CHS in 20 mL of mesitylene in an inert atmosphere box to obtain a 1:20 dilution. This solution was brought out of the inert atmosphere box in a septum vial and approximately 0.2 to 0.4 mL was syringed onto a Whatman filter paper surface, which was placed on sand in a crystalline dish. For safety reasons, the crystalline dish was seated on a ceramic tile in a fume hood. No immediate burning or charring of the filter paper was observed. The experiment was repeated 3 times, yielding the same results.

### CHS-Mesitylene Solution (1:40):

A CHS mesitylene solution was prepared by dissolving 0.5 mL of CHS in 20 mL of mesitylene in an inert atmosphere box to obtain a 1:40 dilution. This solution was brought out of the inert atmosphere box in a septum vial and approximately 0.2 to 0.4 mL was syringed onto a Whatman filter paper surface, which was placed on sand in crystalline dish. For safety reasons, the crystalline dish was seated on a ceramic tile in a fume hood. No immediate burning or charring of filter paper was observed. The experiment was repeated 3 times, yielding the same results.

Both experiments indicate that a CHS mesitylene blend in a concentration of 1:20 to 1:40 shows no pyrophoric behavior. The blend provides a safer option to deliver the CHS to various applications in semiconductor and PV industries.

### Prophetic Example 2

Applicants believe that the disclosed blends may be used in a vapor deposition process to deposit a silicon-containing film. Choosing a solvent that has similar vapor pressure to that of the silicon precursor and which experience has shown to have little to no reactivity with the substrate upon which the silicon-containing film is being deposited is expected to enable vapor deposition processes of these pyrophoric silanes.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

1-13. (canceled)

14. A method of forming a silicon-containing layer on a substrate, the method comprising:
providing a reactor and at least one substrate disposed therein;
introducing into the reactor a vapor of a blend of a silane and a solvent, wherein the silane is selected from the group consisting of (a) a polysilane selected from cyclopentasilane or cyclohexasilane and (b) a monoaminosilane having a formula H₃Si[amine] wherein [amine] is a cyclic amine or —(NR₁R₂) with R₁ and R₂ each independently selected from hydrogen and an aliphatic group having 1 to 6 carbon atoms; and
forming a silicon-containing layer on at least one surface of the substrate using a vapor deposition process.

15. The method of claim 14, wherein the cyclic amine of the monoaminosilane is piperidine or pyrrolidine.

16. The method of claim 14, wherein the silane is selected from the group consisting of diisopropylaminosilane, ditertbutylaminosilane, piperidinosilane, pyrrolidinosilane, and mixtures thereof.

17. The method of claim 14, wherein the solvent is selected from the group consisting of dichloromethane, acetone, pentane, hexane, heptane, octane, decane, dodecane, ethyl ether, and mixtures thereof.

18. The method of claim 17, wherein a silane to solvent ratio is lower than 1 to 2.

19. The method of claim 18, wherein the silane to solvent ratio is lower than 1 to 8.

20. The method of claim 14, wherein the solvent is selected from the group consisting of toluene, mesitylene, xylene, and mixtures thereof.

21. The method of claim 21, wherein a silane to solvent ratio is lower than 1 to 2.

22. The method of claim 22, wherein the silane to solvent ratio is lower than 1 to 8.

23. The method of claim 14, further comprising introducing at least one second precursor into the reactor.

24. The method of claim 23, wherein the second precursor is a metal-containing compound comprising a metal selected from the group consisting of Ti, Ta, Bi, Hf, Zr, Pb, Nb, Mg, Al, Sr, Y, Ba, Ca, Ni, Co, lanthanides, and combinations thereof.

25. The method of claim 14, further comprising introducing at least one co-reactant into the reactor.

26. The method of claim 25, wherein the co-reactant is an oxidizing gas selected from the group consisting of N₂, NH₃, O₂, O₃, H₂O, H₂O₂, carboxylic acid, and combinations thereof.

27. The method of claim 14, wherein the vapor deposition process is a chemical vapor deposition process.

28. The method of claim 14, wherein the vapor deposition process is an atomic layer deposition process.
